(19) United States
(12) Patent Application Publication
(10) Pub. No.: US 2009/0189215 A1
(43) Pub. Date: Jul. 30, 2009

(54) NONVOLATILE FLASH MEMORY DEVICE AND METHOD FOR PRODUCING THE SAME

(75) Inventors: Santanu Kumar Samanta, Singapore (SG); Won Jong Yoo, Gyeonggi-do (KR)

Correspondence Address: FOLEY AND LARDNER LLP;SUITE 500, 3000 K STREET NW, WASHINGTON, DC, 20007, US

(73) Assignee: NATIONAL UNIVERSITY OF SINGAPORE, Singapore (SG)

(21) Appl. No.: 11/912,006

(22) PCT Filed: Apr. 20, 2005
(86) PCT No.: PCT/SG05/00129

§ 371 Date: Feb. 23, 2009

(51) Int. Cl. H01L 29/792; H01L 21/336

(52) U.S. Cl. 257/325; 438/763; 257/E29.309; 257/E21.423

(57) ABSTRACT

A method of producing metallic nanocrystals (107) embedded in high-k dielectric material as well as a nonvolatile flash memory device (100) comprising a discrete charge carrier storage layer, the discrete charge carrier storage layer comprising metallic nanocrystals (107) embedded in high-k dielectric material. In the method described in this invention, firstly an ultra-thin metal film is deposited over a first (105) and a second (106) dielectric layer including high-k dielectric material provided on a substrate (101). Then, the ultra-thin metal film is annealed for forming the metallic nanocrystals (107) on the second dielectric layer (106). Finally, the second dielectric layer (106) and the metallic nanocrystals (107) are covered with a third dielectric layer (108) of high-k dielectric material for forming metallic nanocrystals (107) embedded in high-k dielectric material. The first (105), second (106) and third (108) dielectric layers together with the embedded metallic nanocrystals (107) as the discrete charge carrier storage layer form the nonvolatile flash memory device (100).

### FIELD OF THE INVENTION

This invention relates generally to nonvolatile flash memory devices. In particular, this invention relates to a nonvolatile flash memory device comprising a discrete charge storage layer having metallic nanocrystals embedded in high-k dielectric material. The invention also relates to the fabrication of nonvolatile flash memory devices using metallic nanocrystals embedded in high-k dielectric material as a floating gate.

### BACKGROUND OF THE INVENTION

In recent years, the demand for high density and high performance nonvolatile memory devices has increased to meet the requirements of a range of modern microprocessor-based devices which currently run a variety of functions within cars, personal and portable computers, voice recorders, mobile phones, digital cameras, other wireless products, and industrial control systems. For the future, the “International Technology Roadmap of Semiconductors” (ITRS) 2003 shows that the scale down of nonvolatile flash memory devices will meet serious difficulty. In particular, scaling-down of the conventional polycrystalline silicon based flash memory cell size becomes more and more difficult, because the tunneling oxide thickness cannot be scaled down with the cell size due to the need to keep excellent charge retention and endurance. In order to solve this problem, new types of nonvolatile memory cells, such as discrete nanocrystal nodes (e.g. Si, Ge, SiGe and metal) based memory devices and trap based memory devices (e.g. SONOS, MONOS and SOHOS), are attracting a lot of research attention.

Discrete charge carrier storage resulting from nanocrystals (NCs) and Polysilicon-Oxide-Nitride-Oxide-Silicon (SONOS) type memory devices has been developed because the discreteness of charge carrier storage suppresses lateral migration of charge carriers, hence stored charge carriers are less vulnerable to oxide defects compared with conventional continuous floating gate memory devices.

Metal nanocrystals (NCs) are advantageous for memory devices based on NCs because of the wide range of available work functions, stronger coupling with the conduction channel and smaller energy perturbation due to large barriers for trapped charge carriers. According to simulation results using Wentzel-Kramer-Brillouin (WKB) approximation, leakage current can be reduced as much as two to four orders of magnitude using large work function metals as NCs. Conventionally, metals are forbidden in the front-end of line fabrication of nonvolatile memory devices, but metal in the form of a NC is much more thermodynamically stable and can be integrated with less possibility to damage or contaminate the nonvolatile memory device.

For example, researchers at the National Science Foundation's Center for Advanced Materials and Smart Structures (CAMSS) demonstrated in 2004 arrays of magnetic nickel nanodots having a maximum dimension of 7 nm, and Motorola demonstrated also in 2004 a memory device based on silicon nanocrystals having a storage capacity of 4 MB.

Examples of nonvolatile memory devices of the NC- and SONOS-type are disclosed in the U.S. Pat. Nos. 6,351,411 B2, 6,407,424 B2, 6,413,819 B1, 6,545,314 B2, and 6,724,038 B2.

In WO 2004/048923 A2 to Liu et al., metal NCs using platinum (Pt), silver (Ag), and gold (Au) on a gate oxide comprising silicon dioxide (SiO₂) have been investigated. These metals are chemically inert materials, but can be contaminants in silicon (Si) based fabrication during high temperature treatment. It can clearly be seen that the use of a metal already used in silicon technology is preferable. Since the refractory metal tungsten (W) is widely used as plug for contact metallization in integrated circuit (IC) fabrication, tungsten becomes a good candidate as material for NCs. The work function of tungsten (about 4.6 eV) is larger than the electron affinity of silicon or germanium (about 4.1 eV), resulting in a deeper quantum well. Hence, electrons captured by tungsten nanocrystals (W-NCs) do only escape with difficulty. The mid-gap work function of tungsten can be integrated for both N-MOSFETs and P-MOSFETs to control the threshold voltage. The high melting point and good conductivity of tungsten and the good compatibility of tungsten with silicon processing make W-NCs promising candidates among metal NCs for flash memory applications.

W-NCs embedded in silicon dioxide (SiO₂) based flash memory devices where the floating gate was fabricated by sputtering using a special target composition of dot and matrix materials have already been reported. However, thicker control and tunneling oxides are required to prevent floating gate charge carrier loss between the floating gate and the control gate or the floating gate and the substrate, thus resulting in the requirement of a large voltage to inject charge carriers into the floating gate. Therefore, programming efficiency is decreased due to the thick control and tunneling oxides and a high density of nanocrystals can degrade the device performance due to lateral migration of charge carriers, resulting in poor retention properties.

Direct tunneling through a thin tunneling oxide is most preferable for programming and erasing a nonvolatile flash memory device, but direct tunneling enhances the leakage current which reduces the retention time.

Currently, template technology using aluminum (III) oxide (Al₂O₃) or a polymer template is one of the competing nanocrystal fabrication processes to solve similar problems. However, the pore size of these templates is still large and their fabrication is not compatible with conventional CMOS process technology.

The object of this invention is to provide a nonvolatile flash memory device and a method for fabricating the same, which overcome the above mentioned shortcomings and which provide long retention time, high reliability, and compatibility with conventional CMOS process technology.

### SUMMARY OF THE INVENTION

To increase the programming efficiency and prevent charge loss, physically thick high-k dielectric materials with lower tunneling barriers and equivalent oxide thickness (EOT) are attractive alternatives to replace conventional silicon dioxide. The lower barrier height of high-k dielectric materials allows high currents across the tunneling oxide at low control gate voltages during programming and erasing the nonvolatile flash memory device. A thin tunneling oxide is also more vulnerable to metal contamination.

The invention provides a novel method for assembling metallic nanocrystals embedded in high-k dielectric material for a novel nonvolatile flash memory device using the metallic nanocrystals embedded in high-k dielectric material for storage of charge carriers, which largely improves the data retention and reliability of the nonvolatile flash memory device. The novel method of this invention can be performed with conventional CMOS process techniques. Therefore, the challenge presented in ITRS 2003 can be overcome.

In a first aspect the invention provides a nonvolatile flash memory device that comprises a discrete charge carrier storage layer. This discrete charge carrier storage layer comprises metallic nanocrystals as discrete storage nodes for discretely storing charge carriers, which metallic nanocrystals are embedded in high-k dielectric material. These metallic nanocrystals embedded in high-k dielectric material may be formed with the method according to the second aspect of this invention which is described below.

In the present invention, the term “high-k dielectric material” refers to a dielectric material having a dielectric constant k being clearly higher than 3.9 which is the value of the dielectric constant of silicon dioxide (SiO₂). In some embodiments of the invention, the high-k dielectric material has a dielectric constant k higher than about 5, about 6, about 8 or about 12. Therefore, the nonvolatile memory device of this invention employs metallic nanocrystals with high density and a suitable size distribution as discrete storage nodes for charge carriers. These metallic nanocrystals are insulated by high-quality high-k dielectric material and can be formed using conventional CMOS process technology. Further, the present nonvolatile flash memory device has excellent retention properties in the discrete storage nodes represented by the metallic nanocrystals, while the barrier height from the metallic nanocrystals to the high-k dielectric material is lower than in prior art memory devices, and while the high-k dielectric material has a low EOT. This is inter alia due to the fact that charge carriers (electrons) are not stored in the metallic nanocrystals themselves but are stored in the quantum well caused by the metallic nanocrystals embedded in high-k dielectric material. Taken all this together enables to scale-down the programming voltage as well as the programming time compared with conventional memory devices.

In some embodiments, hafnium oxide-based or zirconium oxide-based high-k dielectric materials are used for embedding the metallic nanocrystals therein. A metal such as cobalt, gold, nickel, palladium, platinum, silver, tungsten or a metal containing compound such as titanium nitride is typically used for forming the metallic nanocrystals.

In one embodiment, hafnium aluminate (HfAlO) is considered one of the suitable high-k dielectric materials, because of its relatively high crystallization temperature (≧1,000° C.) and low leakage current. It has to be briefly noted here that hafnium aluminate (HfAlO) has a dielectric constant k of about 12 to about 18. Moreover, since HfAlO can be deposited by atomic layer deposition (ALD) with excellent control of both layer stoichiometry and thickness, HfAlO deposited by ALD can be used as a control and tunneling oxide. Other materials which have comparable properties, i.e. in particular a dielectric constant in the range of about 5 to about 12 or higher can also be used in which the metal containing nanocrystals are embedded.

Compared with the prior art, the retention and reliability of nonvolatile memory devices can be improved further by this invention. For this reason, the nonvolatile memory devices of this invention can also be used in an extreme environment such as, but limited to, astrospace and radiation.

This invention in addition provides the feasibility of double-bit storage capability, resulting in low cost per stored bit for flash memory products in industry. Further, this invention provides a solution for the programming, retention and reliability problems of the future scaled-down semiconductor flash memory devices, such as beyond 65 nm technology node. This has been marked as “Manufacturable solutions are NOT known” in ITRS 2003.

In a second aspect the invention provides a method of producing metallic nanocrystals embedded in high-k dielectric material. This method comprises the following steps: Firstly, a substrate covered with a first dielectric layer of a first high-k dielectric material is provided. Secondly, a second dielectric layer of a second high-k dielectric material is deposited over the first dielectric layer. Then, a thin metal film, usually an ultra-thin metal film, is deposited over the second dielectric layer. Thereupon, this thin metal film is annealed. Metallic nanocrystals are formed, preferably in a self-assembled manner, from the (ultra-) thin metal film on the second dielectric layer during the annealing. Finally, the second dielectric layer and the metallic nanocrystals are covered with a third dielectric layer of the first high-k dielectric material. Thus, the metallic nanocrystals are embedded in high-k dielectric material.

The first, second and third dielectric layers together with the embedded metallic nanocrystals as the discrete charge carrier storage layer form the nonvolatile flash memory device according to the first aspect of the present invention.

It is noted that the method of the present invention can easily be incorporated in the common production of nonvolatile memory devices since this method is compatible to the conventional CMOS process technology, in particular to the front end processes thereof. This is especially due to the fact that no diffusion of the metallic nanocrystals is observed in the high-k dielectric material upon the annealing step. The annealing step is typically carried out at an elevated temperature, usually at an elevated below the melting point of the used materials.

Further embodiments are described and disclosed in the dependent claims and the detailed description, and will be also become apparent when reading the detailed description of this invention together with the accompanying drawings. The physical and electronic characteristics of one exemplary embodiment of one nonvolatile flash memory device according to the present invention are described in detail hereafter with respect to FIG. 7 to FIG. 14.

### BRIEF DESCRIPTION OF THE DRAWINGS

FIG. 1 shows a schematic cross-sectional view of a nonvolatile flash memory device according to an embodiment of the invention.

FIG. 2 illustrates a simplified fabrication process flow diagram for fabricating the nonvolatile flash memory device shown in FIG. 1.

FIG. 3A to FIG. 3D show four SEM images of the uncompleted nonvolatile flash memory device shown in FIG. 1 with different layers and/or in different fabrication states.

FIG. 4A and FIG. 4B show x-ray photoelectron spectra (XPS) depth profiles taken from layer stacks used in the nonvolatile flash memory device shown in FIG. 1.

FIG. 5A and FIG. 5B show cross-sectional transmission electron microscopy (TEM) images of the nonvolatile flash memory device shown in FIG. 1.

FIG. 6A and FIG. 6B show energy dispersive x-ray spectra (EDX) and a components list for two different spots indicated in FIG. 5B.

FIG. 7 shows the I-V transistor characteristics of the nonvolatile flash memory device shown in FIG. 1.

FIG. 8A and FIG. 8B show the hysteresis loop of double sweep I-V and the gate to substrate C-V curves obtained from the nonvolatile flash memory device shown in FIG. 1.

FIG. 9A and FIG. 9B show the transfer characteristics of the nonvolatile flash memory device shown in FIG. 1 during programming/erasing and the threshold voltage shifts of the nonvolatile flash memory device shown in FIG. 1 after applying programming/erasing voltage pulses.

FIG. 10 shows the threshold voltage shifts of the nonvolatile flash memory device shown in FIG. 1 as a function of programming voltage.

FIG. 11 shows the endurance characteristics of the nonvolatile flash memory device shown in FIG. 1 for program and erase operations.

FIG. 12 shows the retention characteristics of the nonvolatile flash memory device shown in FIG. 1 at room temperature.

FIG. 13 shows a comparison table of the threshold voltage decay rates of nonvolatile flash memory devices of the present invention and of some prior art.

FIG. 14 shows dual mode operations of the nonvolatile flash memory device shown in FIG. 1 by charging source/drain regions and reading at the drain region in different programming/erasing conditions.

### DETAILED DESCRIPTION OF THE INVENTION

In the following detailed description of the invention, reference is made to the accompanying drawings which form a part hereof, and in which are shown, by way of illustration only, specific embodiments of this invention. In the drawings, like numerals describe substantially similar components throughout the several views.

The term substrate used in the following description refers to any doped and/or undoped semiconductor structure that has an exposed surface for the formation of an integrated circuit. Such a semiconductor structure may also comprise other layers that have been fabricated thereupon. Further, the terminals associated with the terms source and drain are determined by operating conditions of the nonvolatile flash memory device formed as a transistor, i.e. the terms source and drain are interchangeable. Additionally, the nonvolatile flash memory device described herein may be part of an arrayed memory, and may further comprise appropriate circuitry for driving and controlling the nonvolatile flash memory device. This circuitry as such is well known in the art and therefore not described in detail herein. Furthermore, the term nanocrystals as used in the present invention means nanocrystalline particles each having a maximum dimension less than or equal to 10 nm, preferably between about 5 nm and about 7 nm, and in particular equal to 5 mm. These nanocrystalline particles are (physically) separated from each other, i.e. do not have contact with each other.

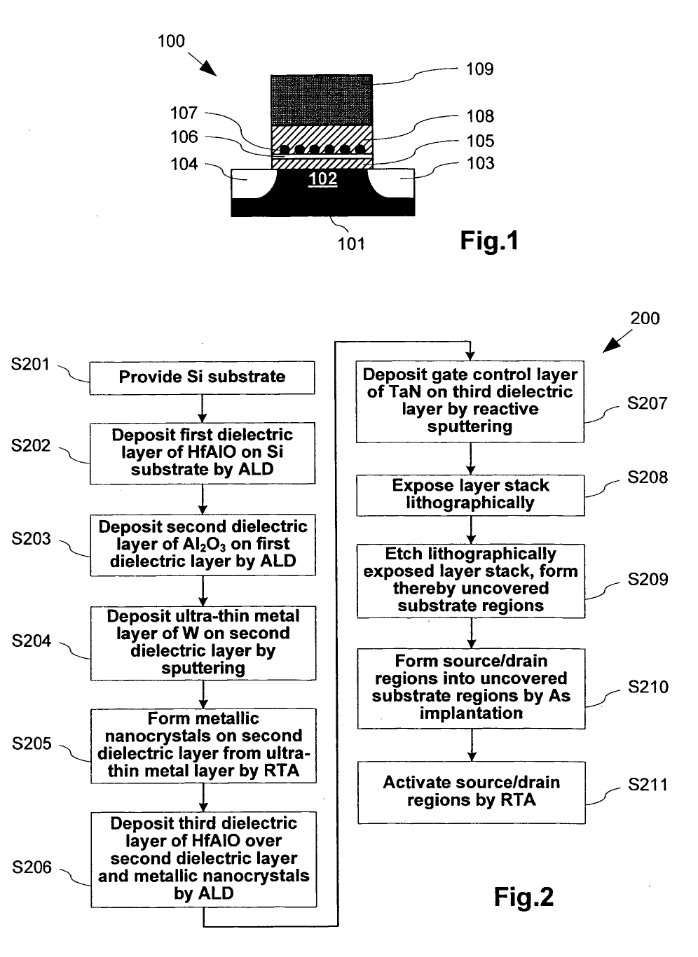

Referring now to FIG. 1, a nonvolatile flash memory device 100 according to an embodiment of this invention is shown. The nonvolatile flash memory device 100 is formed on a substrate 101. A channel region 102 and source/drain regions 103, 104 on opposite sides of the channel region 102 are provided in the substrate 101. The channel region 102 and the source/drain regions 103, 104 are usually provided by suitable doping of appropriate regions of the substrate 101. Above the channel region 102, there are provided a first dielectric layer 105 and a second dielectric layer 106 covering the first dielectric layer 105. On the second dielectric layer 106 there are arranged metallic nanocrystals 107 in a self-assembled manner.

These metallic nanocrystals 107 are distributed substantially two-dimensionally with substantially constant spaces on the second dielectric layer 106. Further, the metallic nanocrystals 107 and the regions of the second dielectric layer 106 left open by the metallic nanocrystals 107 are covered by a third dielectric layer 108. Finally, on top of the third dielectric layer 108 there is provided a control gate layer 109.

The first dielectric layer 105 and the second dielectric layer 106 together represent the tunneling oxide for the metallic nanocrystals 107, and the third dielectric layer 108 represents the control oxide for the metallic nanocrystals 107. Further, the metallic nanocrystals 107 constitute discrete charge carrier storage nodes in a discrete charge carrier storage layer of the nonvolatile flash memory device 100, wherein the discrete charge carrier storage nodes can be compared with a common floating gate layer sandwiched between gate oxide layers. The operation of the nonvolatile flash memory device 100 is known to a person of average skill in the art. Thus, no detailed description thereof is given herein.

According to the invention, the first, second and third dielectric layers 105, 106, 108 are formed of high-k dielectric material. In particular, the same high-k dielectric material may be used for the first and third dielectric layers 105, 108. The second dielectric layer 106 acts as a diffusion barrier layer for the metallic nanocrystals 107 for preventing diffusion of the metallic nanocrystals 107 within the first and third dielectric layers 105, 108. Further, the second dielectric layer 106 prevents contamination of the first dielectric layer 105 with metal of the metallic nanocrystals 107. Furthermore, the second dielectric layer 106 provides low elastic energy and high surface mobility such that the density of the metallic nanocrystals 107 can be increased compared with a device without the second dielectric layer 106.

According to one embodiment of this invention, the substrate 101 comprises silicon (Si), the source/drain regions 103, 104 comprises n⁺-doped silicon (Si) using arsenic (As) as dopant, the metallic nanocrystals 107 comprise tungsten (W), and the first and third dielectric layers 105, 108 comprise hafnium aluminate (HfAlO) having a dielectric constant k₁ of about 12 to 18. In this embodiment, the second dielectric layer 106 comprises aluminum (III) oxide (Al₂O₃) having a dielectric constant k₂ of about 8, and the control gate layer 109 comprises tantalum nitride (TaN). In this embodiment the following alternative materials may also be used: for the substrate 101 strained silicon or silicon on insulator (SOI), for the source/drain regions 103, 104 as dopants phosphorus (P), and for the control gate layer 109 poly-silicon. Since tungsten (W) is used as material for the metallic nanocrystals 107 in the present embodiment, the term “W-NCs” is used as abbreviation for the metallic nanocrystals 107 in the following. However, the term “W-NCs” is by no means restricted to tungsten as the material used for the metallic nanocrystals 107, but other materials examples of which are presented in the following paragraph can also be employed. The metallic nanocrystals 107 typically have a maximum dimension, i.e. an average size, less than or equal to 10 nm, preferably between about 5 nm and about 7 nm, and in particular equal to 5 nm. The metallic nanocrystals 107 are distributed in a self-assembled manner on the second dielectric layer 106 due to the method for forming the metallic nanocrystals 107 as described below with respect to FIG. 2. Further, the metallic nanocrystals 107 are distributed as floating gate in the discrete charge carrier storage layer with a density of about 5×10¹¹/cm². The average size of the metallic nanocrystals 107 and their density are close to the demand of ITRS 2003.

In accordance with the above explanations other materials usable in other embodiments of this invention include, but are not limited to: For the first and third dielectric layers 105, 108 any hafnium oxide-based or zirconium oxide-based high-k dielectric material can for examples be used since hafnium and zirconium belong to the same main group in the periodic table of the elements. Examples of suitable materials that can be used instead of hafnium aluminate (HfAlO) include, but are not limited to, hafnium silicate (HfSiO) having a dielectric constant k of about 3.9 to 26, hafnium silicon oxynitride (HfSiON) having a dielectric constant k of about 5 to 25, or zirconium oxide (ZrO₂) having a dielectric constant k in the range of 20 to 25. Examples of suitable materials that can be used as material for the second dielectric layer 106 instead of aluminum (III) oxide (Al₂O₃) include, but are not limited to, a high-k dielectric material such as silicon (IV) nitride (Si₃N₄) having a dielectric constant k in the range of about 6 to 7, or titanium (IV) oxide (TiO₂) having a dielectric constant k in the range of 20 to 85. Finally, examples metal containing material or metals other than tungsten that can be used for the formation of the metallic nanocrystals 107 include, but are not limited, to cobalt, gold, nickel, palladium, platinum, silver or titanium nitride.

FIG. 2 illustrates a simplified fabrication process flow diagram for fabricating the nonvolatile flash memory device 100 shown in FIG. 1.

In step S201, a bare silicon substrate 101 is provided, which was cleaned by a standard process first. Then, the first dielectric layer 105 is deposited with a thickness in the range of 3 nm to 7 nm, preferably with a thickness of about 5 mm, on the substrate 101 in step S202 by atomic layer deposition (ALD). Since the first dielectric layer 105 comprises hafnium aluminate (HfAlO) in this embodiment of the invention, the used ALD process is based on alternating pulses of the precursors hafnium tetrachloride (HfCl₄) and water (H₂O) on the one hand, and tri-methyl aluminum (Al(CH₃)₃) and water (H₂O) on the other hand. In step S203, the second dielectric layer 106 is deposited in-situ with a thickness in the range of 0.5 nm to 1.5 nm, preferably with a thickness of about 1 nm, on the first dielectric layer 105 also by ALD without breaking vacuum. Since the second dielectric layer 106 comprises aluminum (III) oxide (Al₂O₃) in this embodiment of the invention, the used ALD process is based on pulses of the precursors tri-methyl aluminum (Al(CH₃)₃) and water (H₂O) only. Since aluminum (III) oxide (Al₂O₃) has a higher conduction band offset (experimentally 2.37±0.15 eV and theoretically 2.8 eV) compared to the conduction band offset of hafnium aluminate (HfAlO) (2.1 eV) such that low voltage operation of the nonvolatile flash memory device 100 would not be possible, it has to be guaranteed that the thickness of the second dielectric layer 106 is sufficiently low such that the above mentioned effects do not take effect.

The inventors of this invention found that a thickness of about 1 nm is sufficient to allow low voltage operation of the nonvolatile flash memory device 100 as well as to prevent diffusion of the metallic nanocrystals 107 within the first and third dielectric layers 105, 108. A thin metal layer, typically an ultra-thin metal layer, also named wetting layer, substantially consisting of the metal tungsten (W) is then sputtered with a thickness of between 1 m and 5 nm onto the second dielectric layer 106 in step S204. A sputtering period of between 10 sec and 60 sec, in particular of about 30 sec, a power of 50 W and a pressure of 0.4 Pa (about 3 mT) were used in this sputtering process. As an alternative to sputtering, electron beam evaporation (e-beam evaporation) and atomic layer chemical vapor deposition (ALCVD) can be used for depositing the ultra-thin metal film onto the second dielectric layer 106.

In this fabrication process of the nonvolatile flash memory device 100, the step S204 is immediately followed by step S205, wherein the ultra-thin metal layer is annealed by rapid thermal annealing (RTA). During this RTA in step S205, metallic nanocrystals 107 are formed in a self-assembled manner from the ultra-thin metal layer. Since self-assembly is a thermodynamic process, the density, size and distribution of the metallic nanocrystals 107 can be controlled by optimizing the initial thickness of the ultra-thin metal film, the annealing temperature used for RTA, and the annealing time during which RTA takes place. According to one embodiment of this invention, the RTA is typically carried out in an inert ambient. Any ambient that is chemically inert (unreactive) towards the used materials can be used. The atmosphere can entirely consist or substantially comprise an inert gas such as a noble gas (e.g. xenon, argon) or nitrogen (N₂) or a mixture of such inert gases. Depending on the used materials, the RTA is usually carried out at a temperature between about 500° C. and about 1,000° C., for example between about 900° C. and about 1,000° C., and in one embodiment in which the dielectric layer comprises HfAlO at 950° C. In this last mentioned and other embodiments, the RTA is typically carried out for a time of about between 20 sec and about 2 min, in particular for 60 sec. However, the RTA is by no means limited to the above conditions and can be carried out under any suitable reaction conditions which lead to the formation of nanocrystals that are suitable for practicing the present invention. The determination of suitable annealing conditions is within the knowledge of the person of average skill in the art and can be carried out empirically. This technique as used in the present invention can also be applied to combinations of metallic nanocrystals and high-k substrates, which include but are not limited to, e.g., Au/HfO₂, Au/HfAlO, Au/Al₂O₃, Ag/HfO₂, Ag/HfAlO, Ag/Al₂O₃, Pt/HfO₂, Pt/HfAlO, Pt/Al₂O₃. In addition, the uniformity and size distribution of the metallic nanocrystals 107 can be improved by using suitable equipment such that a highly uniform ultra-thin metal layer is provided. Since the first dielectric layer 105 has and maintains an amorphous structure regardless of any temperature treatment, the surface energy of the metallic nanocrystals 107 on the second dielectric layer 106 is minimized. As already mentioned above with respect to FIG. 1, the metallic nanocrystals 107 are distributed on the second dielectric layer 106 with a density of about 5×10¹¹/cm². If one should refrain from using the second dielectric layer 106 and should form the metallic nanocrystals 107 directly on the first dielectric layer 105, only a density of about 1×10¹¹/cm² can be achieved for the metallic nanocrystals 107. It should be noted that if the ultra-thin metal layer has a thickness greater than 5 nm, then the self-assembly of metallic nanocrystals 107 may not take place due to a too high lattice binding energy of the metal in the ultra-thin metal layer.

Following the step S205, a third dielectric layer 108 is deposited with a thickness of between 8 nm and 10 nm over the metallic nanocrystals 107 and the second dielectric layer 106 in step S206 by ALD. The step S206 is comparable with step S202. Since the third dielectric layer 108, like the first dielectric layer 105, comprises hafnium aluminate (HfAlO) in this embodiment of the invention, the used ALD process is also based on alternating pulses of the precursors hafnium tetrachloride (HfCl₄) and water (H₂O) on the one hand, and tri-methyl aluminum (Al(CH₃)₃) and water (H₂O) on the other hand.

The step S206 is followed by the step S207, wherein a control gate layer 109 comprising tantalum nitride (TaN) is deposited with a thickness of about 150 nm over the third dielectric layer 108 by sputtering. Tantalum nitride (TaN) is used as material for the control gate layer 109 due to its good thermal stability and electrical characteristics when used along with the high-k dielectric materials used in this embodiment of this invention.

The following step S208 represents an appropriate process for lithographically exposing the layer stack comprising the discrete charge carrier storage layer (i.e., having the first, second and third dielectric layers 105, 106, 108 and the metallic nanocrystals 107) and the control gate layer 109. In step S209, this lithographically exposed layer stack is then etched in a suitable etch process for laterally confining the layer stack comprising the trapping layer, and for forming uncovered substrate regions on opposite sides of the laterally confined layer stack. Afterwards, arsenic (As) is implanted into the uncovered substrate regions in step S210 for forming source and drain regions 103, 104 by an implantation process using arsenic ions at an energy of about 100 keV and an area dose of about 1×10¹⁵/cm². The source and drain regions 103, 104 are finally activated in step S211 by RTA at a temperature of about 950° C. and a duration of about 30 sec. Therefore, the source and drain regions 103, 104 consist of n⁺-doped silicon, wherein the n⁺-dopant is arsenic. Then, the nonvolatile flash memory device 100 is completed.

For completeness, it is mentioned here that the resulting transistor structure, which also forms the basis for all following test results, has a width of about 100 μm and a channel length of about 20 μm.

It has to be noted that each individual process used in the above-described steps is commonly known in CMOS production technology. Therefore, the fabrication of the nonvolatile flash memory device 100 of this invention can be easily integrated into common CMOS production.

As every person skilled in the art knows, a plurality of nonvolatile flash memory devices 100 can also be arranged in a memory device array further comprising suitable electronics for storing into and reading from the individual nonvolatile flash memory devices 100 in such a memory device array.

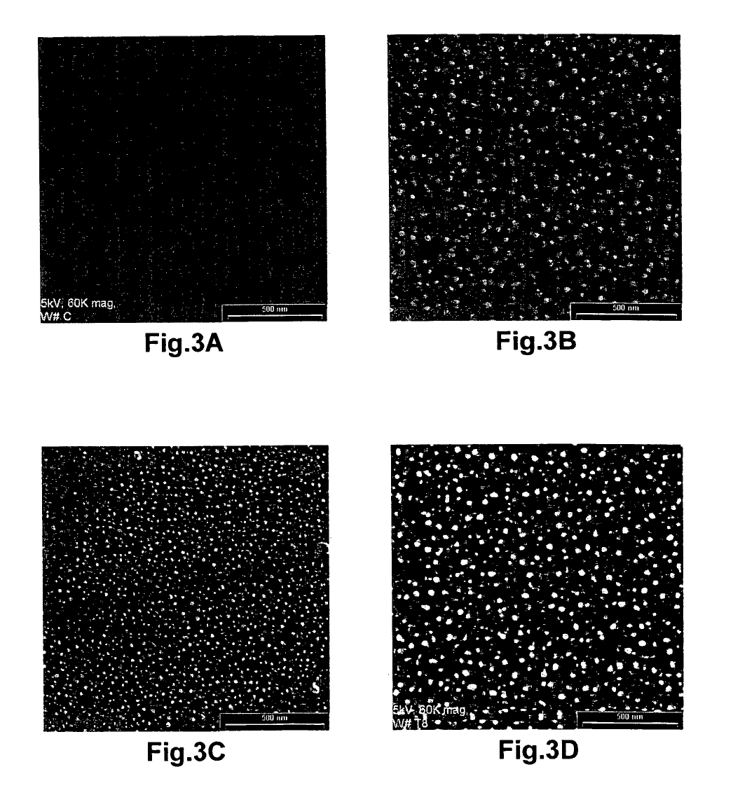

FIG. 3A to FIG. 3D show four scanning electron microcopy (SEM) images of the uncompleted nonvolatile flash memory device 100 (compare FIG. 1) with different layers and/or in different fabrication states.

FIG. 3A shows an SEM image of the uncompleted nonvolatile flash memory device 100 after step S204, i.e. before RTA. In particular, FIG. 3A shows solely the extended surface of the ultra-thin metal film. Further, it is shown in FIG. 3A that metallic nanocrystals 107 cannot be formed without annealing.

FIG. 3B and FIG. 3C show SEM images of the uncompleted nonvolatile flash memory device 100 after step S205, i.e. after RTA. The difference between FIG. 3B and FIG. 3C is that for FIG. 3B step S203 has been skipped whereas for FIG. 3C step S202 has been skipped. I.e., FIG. 3B shows metallic nanocrystals 107 directly on the first dielectric layer 105 without any second dielectric layer 106 in between, and FIG. 3C shows metallic nanocrystals 107 on the second dielectric layer 106 deposited directly on the substrate 101 without any first dielectric layer 105. As can be gathered from FIG. 3B and FIG. 3C, more uniform metallic nanocrystals 107 with a higher density (5×10¹¹/cm²) can be observed on the second dielectric layer 106 (comprising aluminum (III) oxide (Al₂O₃) than on the first dielectric layer 105 (comprising hafnium aluminate (HfAlO) and a density of about 1×10¹¹/cm²). However, as already mentioned above, low voltage operation would not be possible if only aluminum (III) oxide (Al₂O₃) is used as high-k dielectric material, since the conduction band offset of aluminum (III) oxide (Al₂O₃) would be too high (2.8 eV) compared to the conduction band offset (2.1 eV) of hafnium aluminate (Al₂O₃). Therefore, the present invention combines these two effects, i.e. provides a low voltage operation and a high density of the metallic nanocrystals 107 by providing the first and second dielectric layers 105, 106 as described above for FIG. 1.

FIG. 3D shows a SEM image of the uncompleted nonvolatile flash memory device 100 after step S205, i.e. after RTA, with all other previous steps executed. I.e., FIG. 3D shows metallic nanocrystals 107 on a layer stack comprising directly below the metallic nanocrystals 107 the second dielectric layer 106 and underneath the first dielectric layer 105. As can be gathered from FIG. 3D, the metallic nanocrystals 107 distributed on a Si/HfAlO/Al₂O₃ layer stack have a high density which is comparable to metallic nanocrystals 107 distributed solely on a Si/Al₂O₃ layer stack.

Therefore, the nonvolatile flash memory device 100 of this invention provides good charge carrier storage capabilities with good uniformity as well as low programming efficiency, since the metallic nanocrystals 107 are not too small or dispersed. Further, the nonvolatile flash memory device 100 of this invention provides good charge carrier insulation capabilities, since movement of charge carriers due to too large or dense metallic nanocrystals 107, or leakage of charge carriers due to defects in the tunneling or control oxide are avoided. In the nonvolatile flash memory device 100 of this invention, a low programming voltage is achieved using a high-k dielectric material with small conduction band offset, but thin EOT, whereas the charge retention characteristics are improved by using a physically thick high-k dielectric material based on an oxide.

According to this invention, feasibility of double-bit storage capability is shown by selectively injecting charge carriers by means of channel hot electron injection (CHEI) at the source region, at the drain region, and at both source and drain regions.

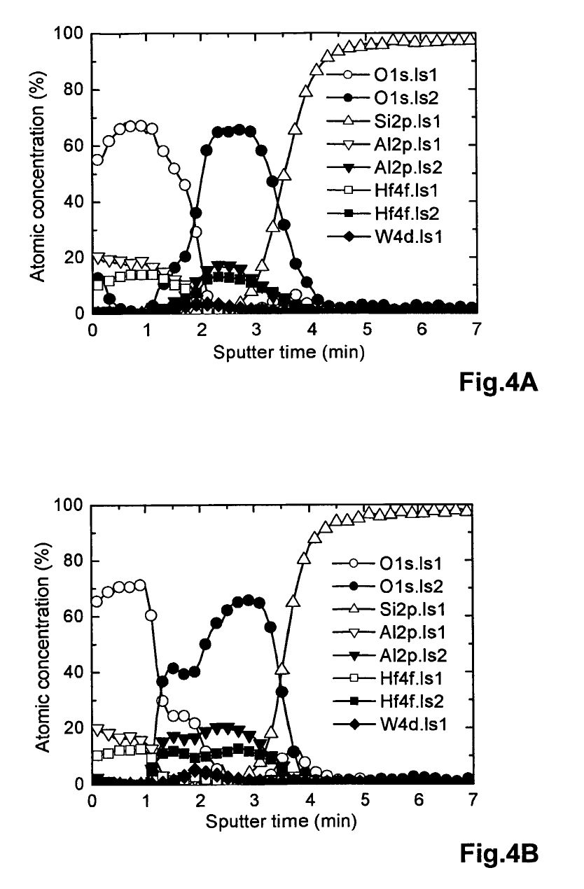

FIG. 4A and FIG. 4B show x-ray photoelectron spectra (XPS) depth profiles taken from layer stacks used in the nonvolatile flash memory device 100 shown in FIG. 1. In particular, FIG. 4A shows the XPS depth profile for a layer stack of Si/HfAlO/W-NCs/HfAlO, whereas FIG. 4B shows that for a layer stack of Si/HfAlO/Al₂O₃/W-NCs/HfAlO (ls1 and ls2 are chosen for a linear square fit during the data analysis process). It can be gatherer from FIG. 4A that there is no distinct second dielectric layer 106 (Al₂O₃) between the W-NCs 107 and the first dielectric layer 105 (HfAlO) after the high temperature annealing for the formation of the self-assembled W-NCs 107. Further, from FIG. 4B it can be gathered that there exists an Al rich layer between the first dielectric layer 105 (HfAlO) and the W-NCs 107. The Al rich layer serves to increase the uniformity and density of the metallic nanocrystals 107, and also lowers the programming voltage compared with Al₂O₃ due to the lower conduction band offset of HfAlO.

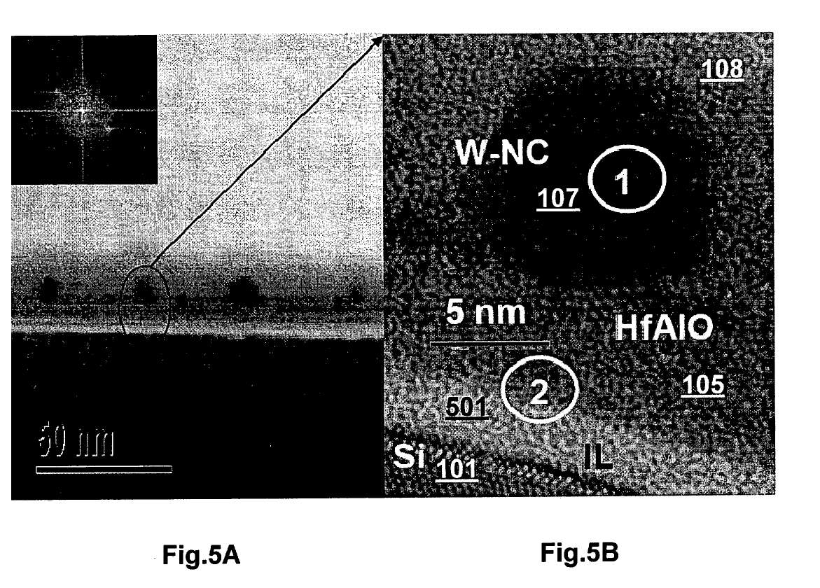

FIG. 5A and FIG. 5B show cross-sectional transmission electron microscopy (TEM) images of the nonvolatile flash memory device 100 shown in FIG. 1. FIG. 5A shows the TEM image of a Si/HfAlO/W-NCs/HfAlO layer stack where spherical W-NCs 107 are formed according to the fabrication process described for FIG. 2 in this invention. A thin interfacial layer (IL) 501 comprising hafnium silicate (HfSiO) between the first dielectric layer 105 and the substrate 101 is formed due to the high temperature treatment during device processing. The TEM image shows clearly the amorphous structure of the first and third dielectric layers 105, 108 (HfAlO) for both the tunneling and control oxides after high temperature treatment at 950° C. for 60 sec. FIG. 5B shows an enlarged high-resolution TEM image of FIG. 5A, in which the lattice structure of the W-NCs 107 extending over about 5 nm can clearly be seen. The inset in FIG. 5A shows the regular pattern of a single electron diffraction (SED) image of one W-NC, which shows that the metallic nanocrystals 107 are really crystalline. Therefore, high quality metallic nanocrystals 107 in terms of shape and crystallinity can be produced by the self-assembly process described in this invention.

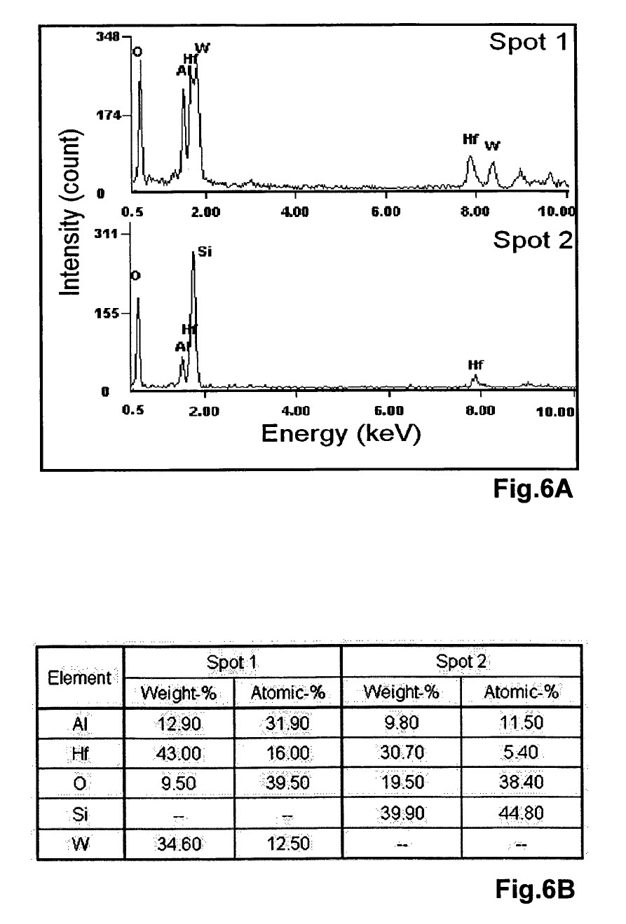

FIG. 6A and FIG. 6B show energy dispersive x-ray spectra (EDX) and a components list for two different spots indicated in FIG. 5B. FIG. 6A shows the possible diffusion of the metal tungsten (W) of the metallic nanocrystals 107 into the control and tunneling oxides using EDX analysis. A strong tungsten (W) signal was detected at the metallic nanocrystals 107 (spot 1), whereas no tungsten (W) signal was found at the interfacial dielectric layers 105, 501 (spot 2).

Also, no diffusion of tungsten (W) is observed into the second dielectric layer 106 (Al₂O₃) and into the Al rich first dielectric layer 105 (HfAlO) (not shown).

FIG. 6B shows a components list for the two different spots indicated in FIG. 5B. It can clearly be gathered from this elements list that tungsten is present in spot 1 with a portion of 34.60 weight-% and 12.50 atomic-%, whereas no tungsten (W) is present at spot 2.

Prior studies have reported that most of platinum (Pt) diffused through an underlying 3 nm thick silicon dioxide (SiO₂) interface during the formation of platinum nanocrystals by annealing at 850-900° C. forms platinum silicide due to reacting with the silicon (Si) of the substrate. According to the EDX analysis in this application, it appears that the diffusion of tungsten (W) is self-limited during the formation of the nanocrystals. Furthermore, it is expected that diffusion of higher melting point metals should be negligible during annealing for the formation of nanocrystals. The EDX result clearly shows that W-NCs are thermodynamically stable, non-diffusive into high-k dielectric materials, and compatible with front end processes.

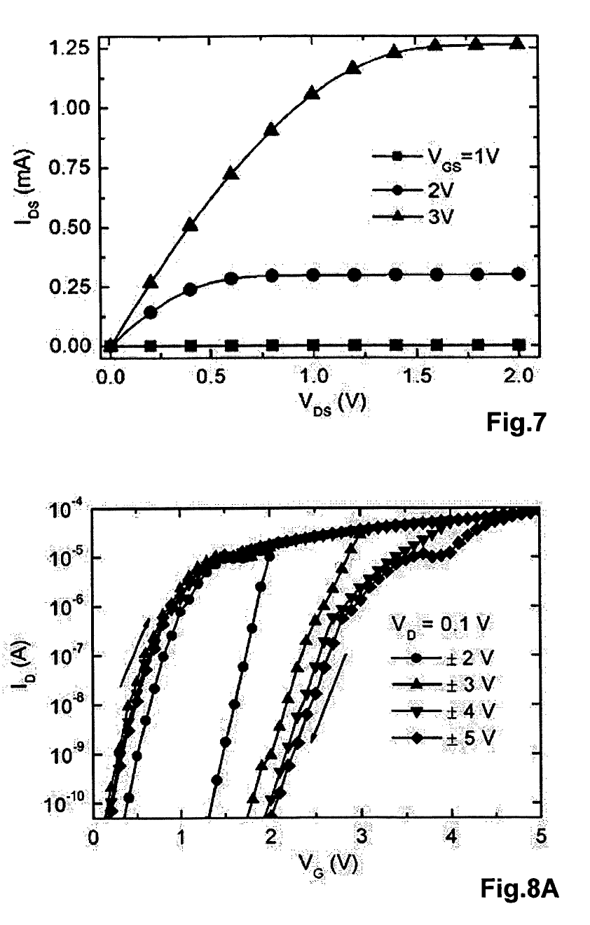

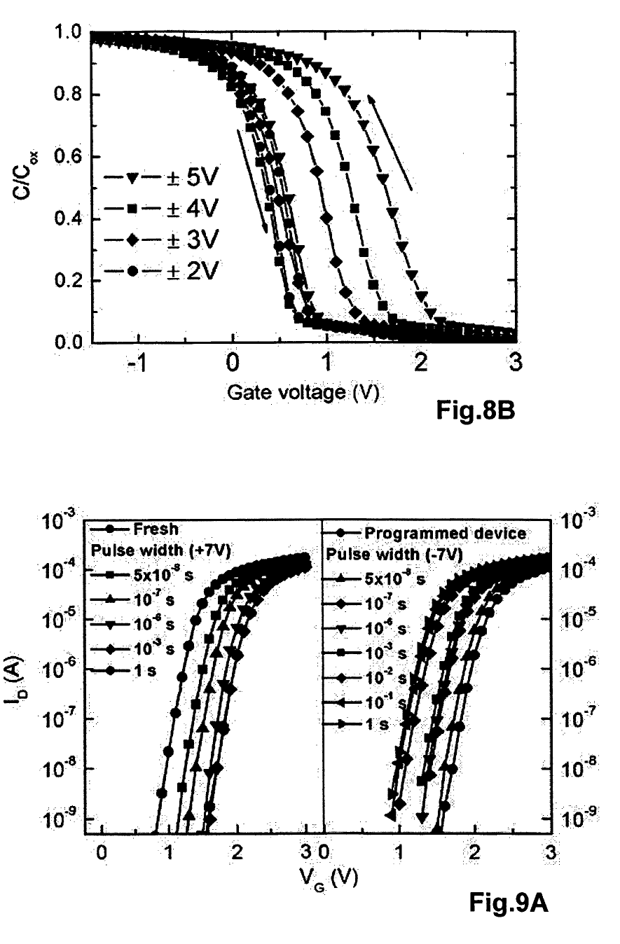

The well behaved I_{DS}-V_{DS} transistor characteristics of a nonvolatile flash memory device 100 (shown in FIG. 1) based on an N-MOS transistor with W-NCs embedded in hafnium aluminate (HfAlO) are shown in FIG. 7, the I_{DS}-V_{DS} transistor characteristics being shown for V_{GS}=1 V, 2 V and 3 V. Therein, V_{DS} and I_{DS} stand for the voltage and the current, respectively, between the drain and source regions 103, 104, and V_{GS} stands for the voltage between the control gate layer 109 and the source region. It can easily be gathered from FIG. 7 that I_{DS} increases with increasing V_{GS}, and that I_{DS} saturates with increasing V_{DS}. FIG. 8A shows the logarithmic I_{D}-V_{G} characteristics of the nonvolatile flash memory device 100 shown in FIG. 1 with gate voltage double sweep ranges of ±2 V, ±3 V, ±4 V and ±5 V. Therein, V_{G} stands for the gate voltage, and I_{D} and V_{D} stand for the current through and the voltage at the drain region, respectively. The threshold voltage shift between the forward and reverse sweeps was found to be 2 V for ±5 V. The shift of I_{D}-V_{G} curve during the reverse sweep is larger compared with the forward one and the threshold voltage saturation is observed at beyond 3 V during the forward sweep. This indicates that the programming is dominated by electron trapping into W-NCs for each case. The same phenomenon is observed in the high frequency gate to substrate C-V hysteresis curves which are shown in FIG. 8B for the nonvolatile flash memory device 100 shown in FIG. 1. Therein, C/Cox stands for the normalized capacitance of the nonvolatile flash memory device 100 shown in FIG. 1.

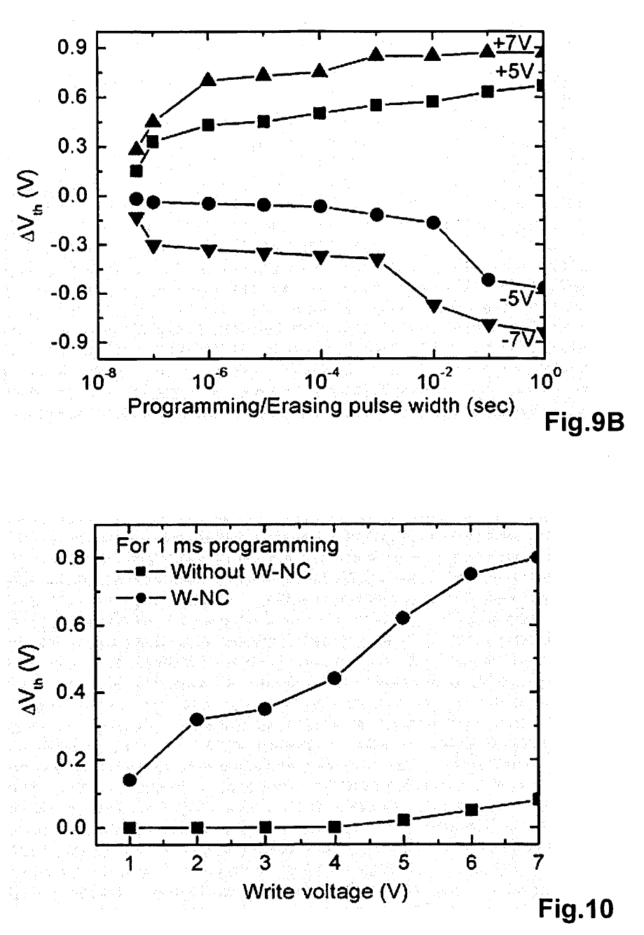

FIG. 9A shows the I_{D}-V_{G} transfer characteristics of the nonvolatile flash memory device 100 shown in FIG. 1 during programming (+)/erasing (−) using voltage pulses of ±7 V with up to 1 sec pulse width. Further, FIG. 9B shows the threshold voltage shifts ΔVₜₕ of the nonvolatile flash memory device 100 shown in FIG. 1 after applying programming (−5 V and −7 V)/erasing (+5 V and +7 V) voltage pulses.

Symmetrical programming and erasing characteristics are observed from FIG. 9A and FIG. 9B. The programming/erasing window is found to be 1.8 V for ±7 V programming/erasing voltage pulses. If the programming speed is defined as the time to reach 90% of ΔVₜₕ, the programming speed in this work is 1 μs at 7 V operating bias which is close to the ITRS 2003 requirement for beyond 2006, whereas in case of W-NCs in silicon dioxide (SiO₂) with a physical thickness of the tunneling oxide of 5 nm the programming speed is about 100 ms at 10 V operating bias. This indicates that the programming speed of W-NCs in hafnium aluminate (HfAlO) is faster than of W-NCs in silicon dioxide (SiO₂). The conduction band offset of the hafnium aluminate (HfAlO) tunneling oxide is 2.1 eV which is lower than the conduction band offset of silicon dioxide (SiO₂) being 3.1 eV. This low electron barrier height enhances the electron tunneling through a triangular potential barrier by Fowler-Nordheim (F-N) conduction mechanism at low programming voltage and a larger part of the applied control gate voltage drops across the tunneling oxide due to the low equivalent oxide thickness (EOT) of hafnium aluminate (HfAlO). This enables low voltage and fast programming in this invention. The threshold voltage shift saturates as the programming/erasing time and voltage increases. This can be due to the presence of a finite number of W-NC nodes embedded in hafnium aluminate (HfAlO) and each node accepts only a finite number of charge carriers (here: electrons) under this testing condition. From the threshold voltage shift after programming at 5 V for 1 μs, the density of charge carriers (Qₜ=(ε/t_{control})ΔVₜₕ, where ε is the dielectric constant of hafnium aluminate (HfAlO) and t_{control} is the thickness of the control oxide) is found to be 3.3×10¹²/cm². Considering a NC density of 5×10¹¹/cm² estimated from the SEM image shown in FIG. 3D, about seven electrons can be injected into a single W-NC after programming at 5 V for 1 its. According to the simulation results reported in the prior art, about ten electrons can be confined in a silicon quantum dot (size: 10 nm×10 nm×6 nm) after 4 V programming for 1 μs. Therefore, the experimental result of this invention is comparable with the simulated result in the prior art.

It is observed from FIG. 9B that the erasing speed is lower than the programming speed under both bias conditions. At thermal equilibrium, the band is aligned such that the mid-gap work function of the metal tungsten (W) creates a deep quantum well (2.6 eV) compared to the conduction band offset of the silicon (Si) substrate (2.1 eV) and the conduction band edge is higher than that of the W-NC. Charge carriers (here: electrons) can be easily injected into the quantum well during programming. On the contrary, the same amount of threshold voltage change during erasing is possible by applying a higher erasing voltage than the programming voltage for the same reason. But in the erasing operation, the abrupt change in threshold voltage is observed after erasing the nonvolatile flash memory device for a long period. This abrupt change takes place earlier under the higher voltage erasing condition. This is not fully understood yet. One possibility may be the abrupt increase in hole capture efficiency in the quantum well with increasing erasing voltage.

In FIG. 10, the programming characteristics (i.e. the threshold voltage shifts) of the nonvolatile flash memory device 100 shown in FIG. 1 as a function of programming voltage are compared with a nonvolatile flash memory device without W-NCs. The devices were programmed at a write voltage V_{G} of between 1 V and 7 V for 1 ms. For the nonvolatile flash memory device 100 shown in FIG. 1, the threshold voltage shift ΔVₜₕ increases with increasing programming voltage V_{G}. A small threshold voltage shift ΔVₜₕ was also observed at a high voltage in the nonvolatile flash memory device without W-NCs due to traps in the high-k dielectric material. It is found that the nonvolatile flash memory device of this invention (i.e. with W-NCs) gives a threshold voltage shift ΔVₜₕ which is 30 times larger than for the nonvolatile flash memory device without W-NCs. This clearly shows that W-NCs are playing a major role during programming.

FIG. 11 shows the endurance characteristics of the nonvolatile flash memory device 100 shown in FIG. 1 for program (write or W) and erase (E) operations to assess the wear-out performance of the nonvolatile flash memory device 100. The endurance was tested using voltage pulses of ±7 V and pulse width of 10 ms per cycle for programming and erasing. In particular, FIG. 11 shows the program/erase threshold voltage window as a function of the number of program/erase cycles. The window remains wide, although a small shift is observed after 10⁵ cycles, perhaps due to some charge trapping/detrapping in the high-k dielectric material.

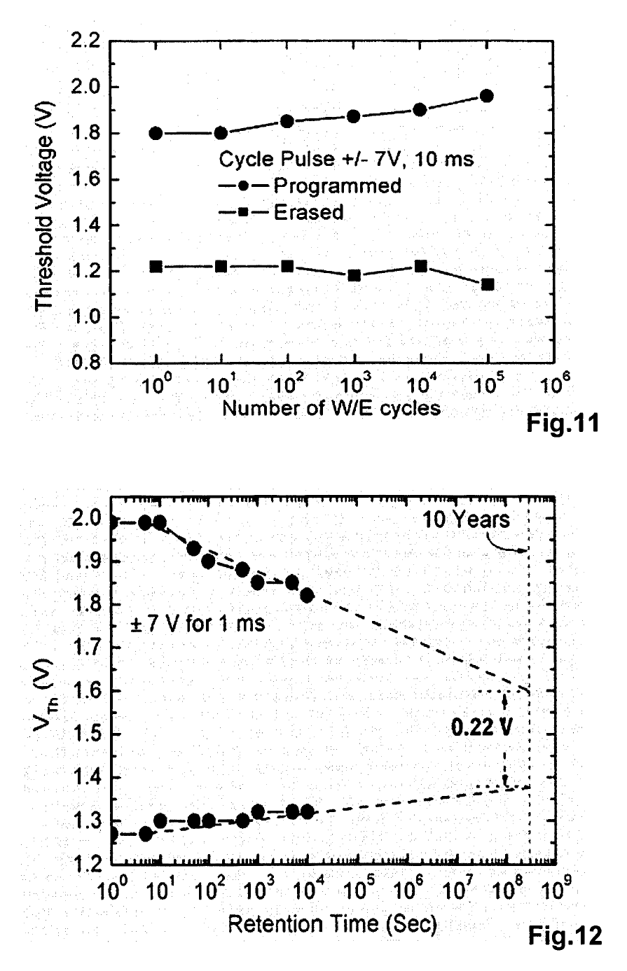

The retention characteristics of the nonvolatile flash memory device 100 shown in FIG. 1 at room temperature is illustrated in FIG. 12. The threshold voltage decay rate is found to be 50 mV/dec after programming with a pulse voltage of 7 V for 1 ms pulse width. The extrapolated memory window is still open at 0.22 V for a retention time of 10 years which is comparable or better with any known discrete nanocrystal memory device. The charge loss observed until 10⁴ sec is much better than the results of W-NCs embedded in tunneling oxide comprising silicon dioxide (SiO₂).

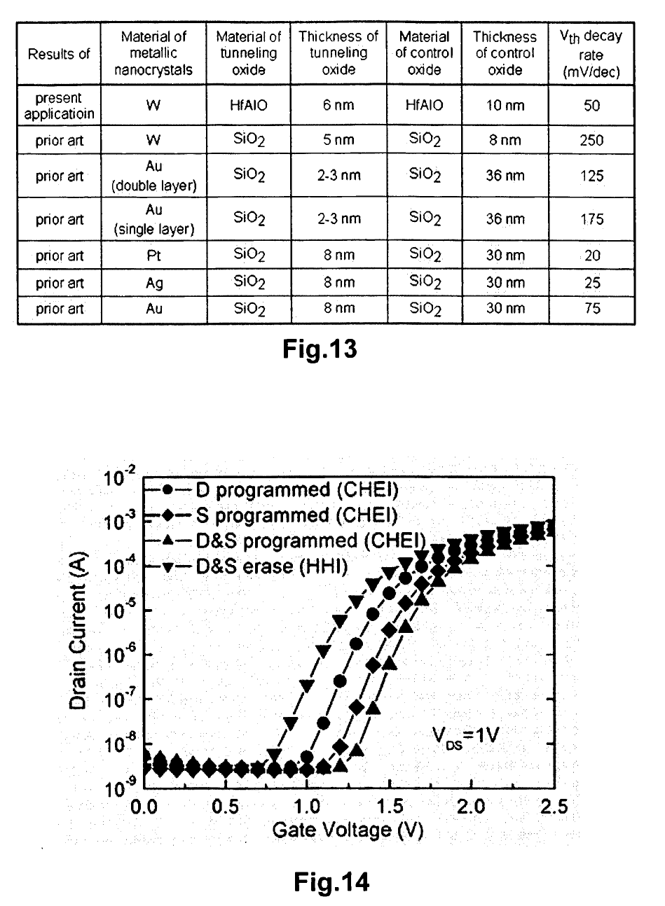

FIG. 13 shows a comparison table of the threshold voltage decay rates of nonvolatile flash memory devices of this invention and of some prior art (WO 2004/048923 A2; Takata M., Kondoh S., Sakaguchi T., Choi H., Shim J. C., Kurino H., and Koyanagi M.: “New non-volatile memory with extremely high density metal nano-dots” in Electron Devices Meeting, 2003, pp. 22.5.1-22.5.4; Lee C., Gorur-Seetharam A., and Kan E. C.: “Operational and reliability comparison of discrete-storage nonvolatile memories: advantages of single- and double-layer metal nanocrystals” in Electron Devices Meeting, 2003, pp. 22.6.1-22.6.4). In particular, FIG. 13 shows that the retention properties of the nonvolatile flash memory device 100 of this invention are better than or at least comparable with that of the different prior art memory devices having metal NCs.

Charge loss from NCs during retention can originate from a stress induced leakage current (SILC) and/or a direct tunneling current through the tunneling oxide, and from a current laterally tunneling from NC to NC. According to prior art simulation results, the potential of a dot is still near the mid-gap of a silicon (Si) channel during the retention mode, and the leakage process of stored electrons requires thermal excitation. Lateral charge distribution due to hopping of charge carriers between adjacent NCs may be one of the causes of threshold voltage decay. A larger memory window can be expected by optimizing the process condition for decreasing the traps in the high-k dielectric material and by designing the device structure for decreasing the leakage current through both the control and the tunneling oxides.

FIG. 14 shows dual mode operations of the nonvolatile flash memory device 100 shown in FIG. 1 by charging source/drain regions and reading at the drain region in different programming/erasing conditions.

Compared with a conventional single-bit cell, a dual-bit cell increases the cell density in a memory device array by reducing the memory cell area from two virtual transistors in place of one. The feasibility of a dual-bit cell in a memory device can be shown through channel hot electron injection (CHEI) programming/Fowler-Nordheim (F-N) erasing with forward/reverse reading, or through local charge storing by CHEI at the source region, at the drain region, and at both the source and drain regions. Since the source and drain regions 103, 104 are symmetrical in the structure of the nonvolatile flash memory device 100 shown in FIG. 1, one of n⁺-doped regions where positive voltage is applied during threshold voltage measurement is considered as drain region in the feasibility test of a two bit storage experiment. In the nonvolatile flash memory device 100 of this invention, charge carriers are locally stored through CHEI at the drain region (V_{D}=5 V, V_{G}=7 V), at the source region (V_{S}=5 V, V_{G}=7 V), and at both the source and drain regions (V_{S}=5 V, V_{G}=7 V followed by V_{D}=5 V, V_{G}=7 V). During CHEI programming, a lateral electric field near the source/drain regions 103, 104 heats the electrons and a transverse electric field between the channel region 102 and the control gate layer 109 injects the electrons into the W-NCs 107. Erasing operation is performed by two-sided hot hole injection (HHI) resulting from band to band tunneling with positive voltages at the source/drain regions 103, 104 and a negative voltage at the control gate layer 109 (V_{S}=5 V, V_{G}=−7 V, V_{D}=5 V). As a result, holes are injected through the tunneling oxide into the W-NCs, where the stored electrons are neutralized by hot holes. The Vₜₕ shown in FIG. 14 was measured by applying a positive bias (1 V) at the drain region and stepping the gate voltage. When electrons are stored at the source region and reading is taken at the drain region, charge carriers localized at the source region will screen the channel region near the source region due to a strong lateral electric field generated by the drain bias and as a result, Vₜₕ (S) is greater than Vₜₕ (D). Due to the storage of charge carriers at both the source and the drain regions, the threshold voltage is at the largest when compared with other charge storage conditions and at the lowest with no charge carriers stored in the trapping layer after HHI. Therefore, four well distinct states are present, which correspond to no charge carriers stored, charge carriers stored only on one side, and charge carriers stored on both sides. The threshold voltage separation of different states can be enhanced by controlling the channel doping. From the results discussed here it is concluded that the high density W-NCs in the trapping layer are well isolated by high-k dielectric material. Due to the high work function of the W-NCs, they are immune to lateral charge migration upon thermal emission from 1 eV to 2 eV shallow traps in a nitride storage layer causing charge migration, which is a clear advantage over known SONOS- or NROM-devices with respect to device scaling. Therefore, it is considered that nonvolatile flash memory devices of this invention with metallic nanocrystals embedded in high-k dielectric material can be used as a two bit-per-cell storage device in a single transistor.

In another embodiment of this invention, a double layer of metallic nanocrystals may be provided above the first and second dielectric layers. This enhances more retention and multi-bit operation properties for such a nonvolatile flash memory device of this invention.

Although this invention has been described in terms of preferred embodiments, it will be understood that numerous variations and modifications may be made, without departing from the spirit and scope of this invention as set out in the following claims.

1-49. (canceled)

50. A nonvolatile flash memory device comprising a discrete charge carrier storage layer, the discrete charge carrier storage layer comprising metallic nanocrystals embedded in high-k dielectric material,
wherein the discrete charge carrier storage layer comprises a layer stack successively having a first dielectric layer, a second dielectric layer and a third dielectric layer, each of the first, second and third dielectric layers comprising high-k dielectric material, and
wherein the metallic nanocrystals are embedded between the second dielectric layer and the third dielectric layer, and the second dielectric layer is a diffusion barrier layer for the metallic nanocrystals.

51. The nonvolatile flash memory device as claimed in claim 50, wherein the first and third dielectric layers comprise a hafnium oxide-based or zirconium oxide-based high-k dielectric material.

52. The nonvolatile flash memory device as claimed in claim 50, wherein the first dielectric layer comprises a thickness between about 3 nm and about 7 nm.

53. The nonvolatile flash memory device as claimed in claim 50, wherein the first dielectric layer comprises a thickness of about 5 nm.

54. The nonvolatile flash memory device as claimed in claim 50, wherein the second dielectric layer comprises a thickness between about 0.5 nm and about 1.5 nm.

55. The nonvolatile flash memory device as claimed in claim 54, wherein the second 5dielectric layer comprises a thickness of about 1 nm.

56. The nonvolatile flash memory device as claimed in claim 50, wherein the third dielectric layer comprises a thickness between about 8 nm and about 10 nm.

57. The nonvolatile flash memory device as claimed in claim 50, wherein the discrete charge carrier storage layer is arranged above a substrate.

58. The nonvolatile flash memory device as claimed in claim 57, wherein the substrate comprises silicon.

59. The nonvolatile flash memory device as claimed in claim 57, wherein a control gate layer is located above the discrete charge carrier storage layer, wherein a channel region is located between the discrete charge carrier storage layer and the substrate, and wherein source and drain regions are located on opposite sides of the channel region on and/or in the substrate.

60. The nonvolatile flash memory device as claimed in claim 50, wherein the first and third dielectric layers comprise a first high-k dielectric material selected from the group consisting of hafnium aluminate (HfAlO), hafnium silicate (HfSiO), hafnium silicon oxynitride (HfSiON), and zirconium oxide (ZrO₂).

61. The nonvolatile flash memory device as claimed in claim 50, wherein the second dielectric layer comprises a second high-k dielectric material selected from the group consisting of aluminum (III) oxide (Al₂O₃), silicon (IV) nitride (Si₃N₄), and titanium (IV) oxide (TiO₂).

62. The nonvolatile flash memory device as claimed in claim 50, wherein the metallic nanocrystals comprise a material selected from the group consisting of cobalt, gold, nickel, palladium, platinum, silver, tungsten, and titanium nitride.

63. The nonvolatile flash memory device as claimed in claim 50, wherein the metallic nanocrystals comprise a maximum dimension of less than or equal to 10 nm.

64. The nonvolatile flash memory device as claimed in claim 63, wherein the metallic nanocrystals comprise a maximum dimension of between about 5 nm and about 7 nm.

65. The nonvolatile flash memory device as claimed in claim 64, wherein the metallic nanocrystals comprise a maximum dimension of equal to 5 nm.

66. The nonvolatile flash memory device as claimed in claim 50, wherein the metallic nanocrystals are distributed in a self-assembled manner.

67. The nonvolatile flash memory device as claimed in claim 50, wherein the metallic nanocrystals are distributed substantially two-dimensionally in the discrete charge carrier storage layer.

68. The nonvolatile flash memory device as claimed in claim 50, wherein the metallic nanocrystals are distributed in the discrete charge carrier storage layer with a density of about 5×10¹¹/cm².

69. A method of producing metallic nanocrystals embedded in high-k dielectric material, comprising:
a) providing a substrate covered with a first dielectric layer of a first high-k dielectric material;
b) depositing a second dielectric layer of a second high-k dielectric material over the first dielectric layer;
c) depositing an ultra-thin metal film over the second dielectric layer;
d) annealing the ultra-thin metal film, thereby forming metallic nanocrystals on the second dielectric layer; and
e) covering the second dielectric layer and the metallic nanocrystals with a third dielectric layer of the first high-k dielectric material such that the metallic nanocrystals are embedded between the second dielectric layer and the third dielectric layer, thereby forming metallic nanocrystals embedded in high-k dielectric material, wherein the second dielectric layer is a diffusion barrier layer for the metallic nanocrystals.

70. The method as claimed in claim 69, wherein step d) is carried out in a substantially inert ambient.

71. The method as claimed in claim 69, wherein step d) is carried out in an ambient substantially comprising nitrogen.

72. The method as claimed in claim 69, wherein step d) is carried out at a temperature between about 500° C. and about 1,000° C.

73. The method as claimed in claim 69, wherein step d) is carried out at a duration of between 20 sec and 2 min.

74. The method as claimed in claim 69, wherein the first high-k dielectric material used in steps a) and e) is a hafnium oxide-based or zirconium oxide-based high-k dielectric material.

75. The method as claimed in claim 74, wherein the first high-k dielectric material used in steps a) and e) is selected from the group consisting of hafnium aluminate (HfAlO), hafnium silicate (HfSiO), hafnium silicon oxynitride (HfSiON), and zirconium oxide (ZrO₂).

76. The method as claimed in claim 69, wherein the second high-k dielectric material used in step b) is selected from the group consisting of aluminum (III) oxide (Al₂O₃), silicon (IV) nitride (Si₃N₄), and titanium (IV) oxide (TiO₂).

77. The method as claimed in claim 69, wherein in step c) a metallic material is used, which metallic material is selected from the group consisting of cobalt, gold, nickel, palladium, platinum, silver, tungsten, and titanium nitride.

78. The method as claimed in claim 69, wherein in step d) metallic nanocrystals are formed, the maximum dimension of which is less than or equal to about 10 nm.

79. The method as claimed in claim 78, wherein in step d) metallic nanocrystals are formed, the maximum dimension of which is between about 5 nm and about 7 nm.

80. The method as claimed in claim 69, wherein in step d) metallic nanocrystals are formed, which are distributed in a self-assembled manner.

81. The method as claimed in claim 69, wherein in step d) metallic nanocrystals are formed, which are distributed substantially two-dimensionally on the second dielectric layer.

82. The method as claimed in claim 69, wherein in step d) metallic nanocrystals are formed, which are distributed on the second dielectric layer with a density of about 5×10¹¹/cm².

83. The method as claimed in claim 69, wherein the first dielectric layer in step a) is provided with a thickness between about 3 nm and about 7 nm.

84. The method as claimed in claim 69, wherein the first dielectric layer is provided in step a) by atomic layer deposition of the first high-k dielectric material onto the substrate.

85. The method as claimed in claim 69, wherein the second dielectric layer is deposited in step b) with a thickness between about 0.5 nm and about 1.5 nm.

86. The method as claimed in claim 69, wherein the second dielectric layer is deposited in step b) by atomic layer deposition of the second high-k dielectric material onto the first dielectric layer.

87. The method as claimed in claim 69, wherein the ultra-thin metal layer is deposited in step c) with a thickness of between about 1 nm and about 5 nm.

88. The method as claimed in claim 69, wherein the ultra-thin metal layer is deposited in step c) by sputtering metal onto the second dielectric layer.

89. The method as claimed in claim 88, wherein in step c) the metal is sputtered for a sputtering period of between about 10 sec and about 60 sec.

90. The method as claimed in claim 88, wherein in step c) the metal is sputtered for a sputtering period of about 30 sec.

91. The method as claimed in claim 69, wherein the third dielectric layer is deposited in step e) with a thickness of between about 8 nm and about 10 nm.

92. The method as claimed in claim 69, wherein the third dielectric layer is deposited in step e) by atomic layer deposition of the first high-k dielectric material onto the second dielectric layer and the metallic nanocrystals.

93. The method as claimed in claim 69, wherein the first dielectric layer in step a) is provided on a substrate comprising silicon.
